(19) United States
(12) Patent Application Publication
(10) Pub. No.: US 2014/0355646 A1
(43) Pub. Date: Dec. 4, 2014

(54) PIEZOELECTRIC DEVICE PACKAGE AND METHOD OF FABRICATING THE SAME

(71) Applicant: SAMSUNG ELECTRO-MECHANICS CO., LTD., Suwon-Si (KR)

(72) Inventors: Jong Pil LEE, Suwon-Si (KR); Sang Yeob CHA, Suwon-Si (KR); Soon Bum LEE, Suwon-Si (KR); Jong Beom JEON, Suwon-Si (KR); Katsushi YASUDA, Suwon-Si (KR)

(73) Assignee: SAMSUNG ELECTRO-MECHANICS CO., LTD., Suwon-Si (KR)

(21) Appl. No.: 14/294,749

(22) Filed: Jun. 3, 2014

(30) Foreign Application Priority Data
Jun. 3, 2013 (KR) 10-2013-0063532

(51) Int. Cl. G01K 7/32; H01L 41/25

(52) U.S. Cl. CPC G01K 7/32; H01L 41/25
USPC 374/117; 29/25.35

(57) ABSTRACT

A piezoelectric device package may include: a case having a plurality of terminals disposed on a lower surface thereof; a piezoelectric device disposed in the case; a temperature measuring device disposed on one surface of the piezoelectric device in the case and having a thin film form; and a cover member enclosing an upper portion of the case.

### CROSS-REFERENCE TO RELATED APPLICATION

This application claims the benefit of Korean Patent Application No. 10-2013-0063532 filed on Jun. 3, 2013, with the Korean Intellectual Property Office, the disclosure of which is incorporated herein by reference.

### BACKGROUND

The present disclosure relates to a piezoelectric device package and a method of fabricating the same, and more particularly, to a piezoelectric device package capable of solving a frequency matching problem due to a temperature deviation by accurately measuring a temperature of a piezoelectric device, and a method of fabricating the same.

A quartz vibrator is commonly known as a quartz oscillator and is fabricated by forming electrodes of a conductive material such as Au or Ag on both surfaces of a thin quartz vibrator. When a voltage is applied to the electrodes, deformation force occurs due to an electrostrictive effect, and vibrations occur by the deformation force. When the vibrations occur, a voltage is generated in the electrode by a piezoelectric effect. In this case, a frequency depending on the vibrations is determined depending on dynamic properties or a size of the thin quartz vibrator. Generally, the thin quartz vibrator is stable with respect to a change in temperature, or the like, and has a very high Q value.

In order to control a frequency in a mobile communications apparatus using these properties, the quartz vibrator is used. The quartz vibrator should maintain a stable frequency constant with respect to a change in an external temperature in a wide use temperature range.

However, the quartz vibrator may demonstrate frequency change characteristics with respect to an actual temperature. Therefore, a quartz vibrator having more stable and accurate characteristics by including a compensating circuit compensating for a frequency depending on the temperature to decrease a change in the frequency depending on the temperature may be implemented.

The following Related Art Document (Patent Document 1) relates to a multi quartz vibrator and a method of fabricating the same.

The following Patent Document 1 uses a temperature measuring device in chip form, unlike the present disclosure, such that precise correction of a frequency of a piezoelectric device depending on a temperature, which is possible in the present disclosure using a temperature measuring device in a thin film form, is impossible.

### RELATED ART DOCUMENT

(Patent Document 1) Korean Patent Laid-Open Publication No. 2012-0052821

### SUMMARY

An aspect of the present disclosure may provide a piezoelectric device package capable of significantly decreasing a difference between a temperature of a temperature measuring device and a temperature of a piezoelectric device, and a method of fabricating the same.

According to an aspect of the present disclosure, a piezoelectric device package may include: a case having a plurality of terminals disposed on a lower surface thereof; a piezoelectric device disposed in the case; a temperature measuring device disposed on one surface of the piezoelectric device in the case and having a thin film form; and a cover member enclosing an upper portion of the case.

The piezoelectric device package may be disposed by sequentially stacking the temperature measuring device and the piezoelectric device from a bottom.

The piezoelectric device may have a first excitation electrode disposed on an upper surface thereof and have a second excitation electrode disposed on a lower surface thereof, the first and second excitation electrodes being extendedly disposed on corners of the lower surface of the piezoelectric device, respectively.

The temperature measuring device may have first piezoelectric device connecting electrodes disposed on some of corners thereof so as to correspond to the corners of the piezoelectric device on which the first and second excitation electrodes are disposed.

The piezoelectric device may have dummy electrodes disposed on some corners of a lower surface thereof.

The plurality of terminals may include a temperature measuring device input terminal, a temperature measuring device output terminal, a piezoelectric device input terminal, and a piezoelectric device output terminal respectively disposed corners of a lower surface of the case in a clockwise direction or a counterclockwise direction.

The cover member may be disposed of a metal.

One of the terminals and the cover member may be electrically connected to each other.

According to another aspect of the present disclosure, a method of fabricating a piezoelectric device package may include: mounting a temperature measuring device having a thin film form in a case; mounting a piezoelectric device in the case; and coupling a cover member to an upper portion of the case.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic exploded perspective view of a piezoelectric device package according to an exemplary embodiment of the present disclosure;

FIG. 2 is a schematic cross-sectional view taken along line A-A′ of FIG. 1;

FIG. 3A is a graph showing temperatures of a piezoelectric device and a temperature measuring device depending on an operation time according to the related art; and FIG. 3B is a graph showing a temperature difference between a piezoelectric device and a temperature measuring device depending on an operation time according to an exemplary embodiment of the present disclosure;

FIG. 4 is a circuit diagram of the piezoelectric device package according to an exemplary embodiment of the present disclosure;

FIG. 5 is a top view of the piezoelectric device package according to an exemplary embodiment of the present disclosure; and

FIG. 6 is a bottom view of the piezoelectric device package according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

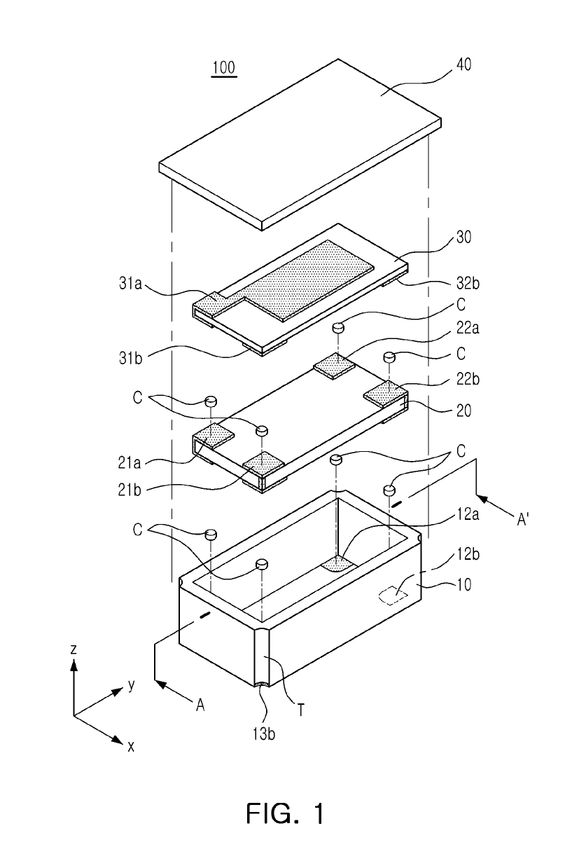

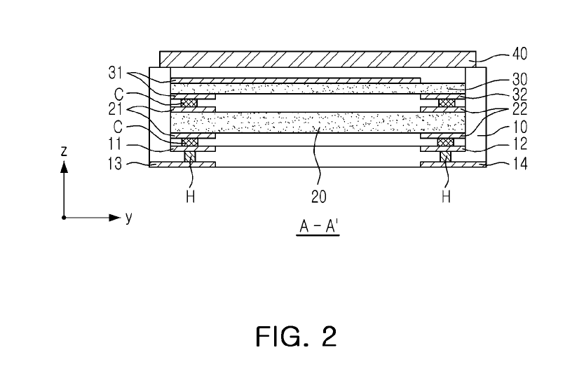

FIG. 1 is a schematic exploded perspective view of a piezoelectric device package 100 according to an exemplary embodiment of the present disclosure; and FIG. 2 is a schematic cross-sectional view taken along line A-A′ of FIG. 1.

A structure of a piezoelectric device package 100 according to an exemplary embodiment of the present disclosure will be described with reference to FIGS. 1 and 2.

The piezoelectric device package 100 according to an exemplary embodiment of the present disclosure may include a case 10, a temperature measuring device 20 and a piezoelectric device 30 mounted in the case 10, and a cover member 40 positioned above the case 10.

In more detail, the piezoelectric device package 100 according to an exemplary embodiment of the present disclosure may include the case 10 having a plurality of terminals disposed on a lower surface thereof; the piezoelectric device 30 disposed in the case 10; the temperature measuring device 20 disposed on one surface of the piezoelectric device 30 in the case 10 and having a thin film form; and the cover member 40 enclosing the case 10.

The piezoelectric device 30 may be disposed by cutting a quartz plate formed of SiO₂ and forming first and second excitation electrodes 31a and 31b formed on upper and lower surfaces of the quartz plate, respectively. The piezoelectric device 30 may be electrically connected to a piezoelectric device input terminal and a piezoelectric device output terminal by a second piezoelectric device connecting electrode 11 formed in the case to thereby be directly connected to an external integrated circuit.

The first and second excitation electrodes 31a and 31b may be extendedly formed on corners of the lower surface of the piezoelectric device 30, respectively.

The piezoelectric device 30 and the temperature measuring device 20 maybe electrically connected to each other by connecting parts C.

The piezoelectric device may include the first and second excitation electrodes 31a and 31b in order to be connected to the external integrated circuit.

The first excitation electrode 31a may serve as an input terminal of the piezoelectric device 30, and the second excitation electrode 31b may serve as an output terminal of the piezoelectric device 30.

The first and second excitation electrodes 31a and 31b may be connected, respectively, to first piezoelectric device connecting electrodes 21a and 21b formed on the temperature measuring device 20 to be electrically connected, respectively, to second piezoelectric device connecting electrodes 11a and 11b positioned in the case 10, such that they may be electrically connected to an integrated circuit.

That is, in the piezoelectric device package 100 according to an exemplary embodiment of the present disclosure, the temperature measuring device 20 and the piezoelectric device 30 are stacked in the case 10, such that the piezoelectric device package 100 may be simply completed, and an interval between the temperature measuring device 20 and the piezoelectric device 30 may be significantly decreased through the electrical connection as described above.

The piezoelectric device 30 may have dummy electrodes 32a and 32b formed on some corners of a lower surface thereof.

The dummy electrodes 32a and 32b may be connected to temperature measuring device input and output electrodes 22a and 22b of the temperature measuring device 20 through the connecting parts C.

The dummy electrodes 32a and 32b are connected to the temperature measuring device 20 to increase adhesion of the piezoelectric device 30, such that a phenomenon that the piezoelectric device 30 is separated by external impact is prevented, whereby reliability of the piezoelectric device package 100 may be improved.

Referring to FIG. 2, the temperature measuring device 20 may be mounted below the piezoelectric device 30 in the case 10. Therefore, the temperature measuring device 20 may be closely adhered to the piezoelectric device 30, such that an internal temperature of the case 10 in which the piezoelectric device 30 is mounted may be measured.

The temperature measuring device 20 may be closely adhered to an upper surface or a lower surface of the piezoelectric device 30 and may have the thin film form.

The temperature measuring device 20 maybe a thermistor, but is not limited thereto.

In addition to the thermistor, a thin film temperature measuring device capable of measuring an internal temperature of the piezoelectric device package and transferring information on the measured temperature to the external integrated circuit (IC) may be used.

Since the thermistor is connected to a power supply and has a predetermined resistance value depending on a temperature of the thermistor, a temperature of the piezoelectric device package 100 in which the thermistor is mounted may be measured by measuring the resistance value of the thermistor.

The temperature measured in the scheme as described above may be received in the integrated circuit and be used as a value for compensating for a temperature-frequency change of the piezoelectric device 30 mounted in the piezoelectric device package 100.

According to an exemplary embodiment of the present disclosure, the temperature measuring device 20 may include the temperature measuring device input and output electrodes 22a and 22b, wherein the temperature measuring device input electrode 22a is connected to a power supply and the temperature measuring device output electrode 22b is connected to an integrated circuit to measure a resistance value depending on temperature-resistance change characteristics depending on a predetermined voltage, thereby measuring the temperature value.

The temperature measuring device input and output electrodes 22a and 22b may be electrically connected to a temperature measuring device connecting electrode 12 formed on a bottom surface in the case 10.

At least one of a plurality of terminals 13 and 14 formed on the lower surface of the case 10 may be electrically connected to the cover member 40 through a penetration part T.

The cover member 40 may be formed of a material having excellent conductivity to serve as a ground of the piezoelectric device 30 or the temperature measuring device 20.

The cover member 40 may serve as the ground to prevent noise when the piezoelectric device package 100 generates a frequency and to significantly decrease an influence from the outside.

The cover member 40 may be formed of copper (Cu), but is not limited thereto.

The cover member 40 may serve as the ground, such that a separate process and component for a ground are not required.

The second piezoelectric device connecting electrodes 11a and 11b and temperature measuring device connecting electrodes 12a and 12b formed in the case 10 maybe electrically connected to the terminals 13 and 14 formed on the lower surface through conductive vias H, respectively.

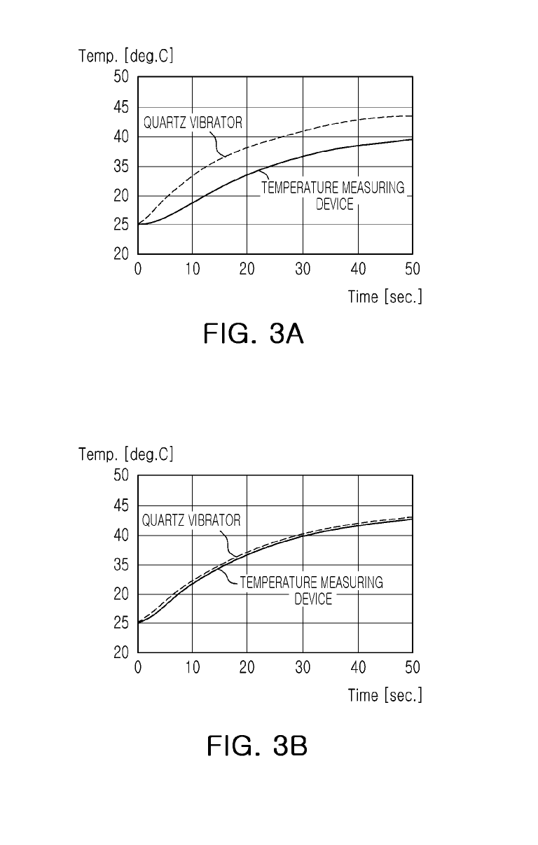

FIG. 3A is a graph showing temperatures of a piezoelectric device and a temperature measuring device depending on an operation time according to the related art; and FIG. 3B is a graph showing a temperature difference between a piezoelectric device and a temperature measuring device depending on an operation time according to an exemplary embodiment of the present disclosure.

According to the related art, since a wide interval can not but be formed between the temperature measuring device and the piezoelectric device, a temperature difference can not but be generated between the temperature measuring device and the piezoelectric device.

Referring to FIG. 3A, it may be appreciated that as an operation time becomes long, the temperature difference between the temperature measuring device and the piezoelectric device is gradually increased.

However, in the case of the piezoelectric device package 100 according to an exemplary embodiment of the present disclosure, the temperature measuring device 20 having the thin film form is used, such that the interval between the temperature measuring device 20 and the piezoelectric device 30 may be relatively very narrow.

Therefore, the temperature difference between the piezoelectric device 30 and the temperature measuring device 20 may be significantly decreased. As a result, a temperature deviation between the piezoelectric device 30 and a frequency is decreased, whereby the piezoelectric device package 100 having more stable and accurate characteristics may be provided.

When the temperature measuring device is mounted outside the case 10, an accurate temperature of the piezoelectric device may not be measured. Therefore, it was difficult to compensate for an accurate temperature deviation depending on a temperature-frequency change.

However, according to an exemplary embodiment of the present disclosure, the temperature measuring device 20 closely adhered to the piezoelectric device 30 may measure the temperature of the piezoelectric device 30, thereby measuring an accurate temperature of the piezoelectric device 30. Therefore, an accurate temperature deviation depending on a temperature-frequency change may be compensated for. As a result, precision of a frequency of the piezoelectric device package 100 may be secured.

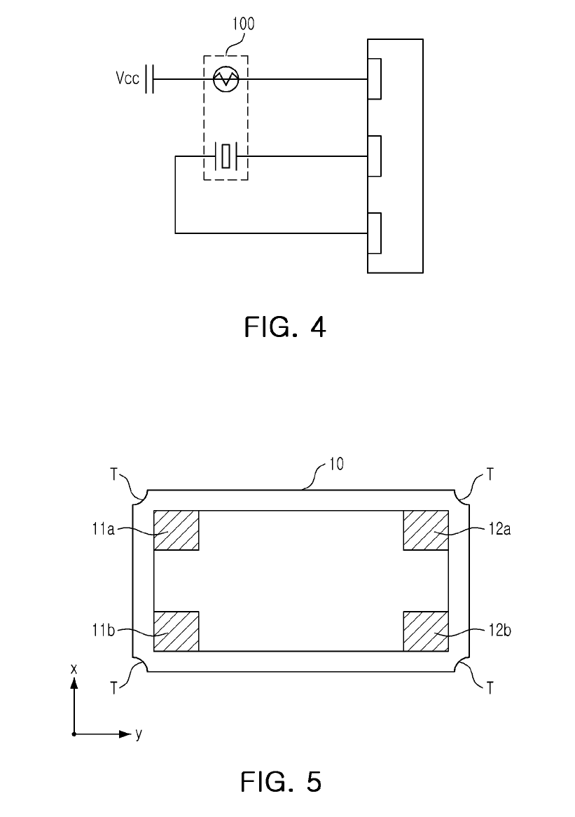

FIG. 4 is a circuit diagram of the piezoelectric device package according to an exemplary embodiment of the present disclosure.

The temperature measuring device 20 may be connected to a power supply Vcc and may have an appropriate resistance value depending on a temperature.

As a result, an internal temperature of the case 10 may be measured by measuring the resistance value of the temperature measuring device 20.

The measured temperature may be input to an integrated circuit (IC) including a temperature compensating circuit, and the integrated circuit (IC) may receive a frequency from the piezoelectric device 30, which is a frequency supplying source, and compensate for received frequency change characteristics depending on a temperature of the received frequency to solve a frequency matching problem due to a temperature deviation.

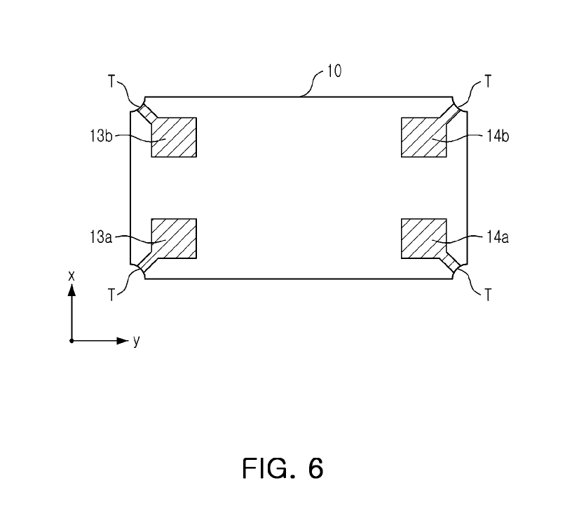

FIG. 5 is a top view of the case 10 according to an exemplary embodiment of the present disclosure; and FIG. 6 is a bottom view of the case 10 according to an exemplary embodiment of the present disclosure.

Referring to FIG. 5, the second piezoelectric device connecting electrodes 11a and 11b and the temperature measuring device connecting electrodes 12a and 12b may be formed in the case 10.

The second piezoelectric device connecting electrodes 11a and 11b may be electrically connected, respectively, to the first piezoelectric device connecting electrodes 21a and 21b formed on the temperature measuring device 20 to thereby be electrically connected to the first and second excitation electrodes 31a and 31b, respectively.

The temperature measuring device connecting electrodes 12a and 12b may be electrically connected, respectively, to the temperature measuring device input and output electrodes 22a and 22b formed on the temperature measuring device 20.

Referring to FIG. 6, the plurality of terminals 13 and 14 may be formed on the corners of the lower surface of the case 10.

The plurality of terminals may include a temperature measuring device input terminal, a temperature measuring device output terminal, a piezoelectric device input terminal, and a piezoelectric device output terminal.

The respective terminals 13 and 14 may be electrically connected to the second piezoelectric device connecting electrodes 11a and 11b and the temperature measuring device connecting electrodes 12a and 12b formed in the case 10 through the conductive vias H, respectively.

In addition, the case 10 may have a ground terminal (not shown) additionally formed on the lower surface thereof.

A method of fabricating a piezoelectric device package 100 according to another exemplary embodiment of the present disclosure may include mounting a temperature measuring device 20 having a thin film form in a case 10; mounting a piezoelectric device 30 in the case 10; and coupling a cover member 40 to an upper portion of the case 10.

The temperature measuring device 20 having second piezoelectric device connecting electrodes 11a and 11b and temperature measuring device input and output electrodes 22a and 22b formed thereon and the piezoelectric device 30 having first and second excitation electrodes 31a and 31b formed thereon may be mounted in the case 10.

Since the case 10, the temperature measuring device 20, and the piezoelectric device 30 have corresponding electrodes formed thereon and therebeneath, respectively, the piezoelectric device package 100 may be completed by sequentially stacking the temperature measuring device 20 and the piezoelectric device 30 in the case 10.

That is, a separate process of positioning the temperature measuring device 20 may not be required, and a process of forming a cavity at which the temperature measuring device 20 is to be positioned in the case may not be required.

As set forth above, with the piezoelectric device package according to an exemplary embodiment of the present disclosure, the temperature measuring device having the thin film form is used, whereby the temperature difference between the piezoelectric device and the temperature measuring device may be significantly decreased.

In detail, the temperature of the piezoelectric device may be accurately measured. Therefore, the temperature deviation between the piezoelectric device and the frequency is decreased, whereby the piezoelectric device having more stable and accurate characteristics may be provided.

According to an exemplary embodiment of the present disclosure, the method of fabricating a piezoelectric device package capable of maintaining a constant and stable frequency with respect to a change in an external temperature by measuring an accurate temperature of the piezoelectric device by a simple method may be provided.

While exemplary embodiments have been shown and described above, it will be apparent to those skilled in the art that modifications and variations could be made without departing from the spirit and scope of the present disclosure as defined by the appended claims.

What is claimed is:

1. A piezoelectric device package comprising:
a case having a plurality of terminals disposed on a lower surface thereof;
a piezoelectric device disposed in the case;
a temperature measuring device having a thin film form and disposed on one surface of the piezoelectric device in the case; and
a cover member enclosing an upper portion of the case.

2. The piezoelectric device package of claim 1, wherein it is disposed by sequentially stacking the temperature measuring device and the piezoelectric device from a bottom.

3. The piezoelectric device package of claim 1, wherein the piezoelectric device has a first excitation electrode disposed on an upper surface thereof and has a second excitation electrode disposed on a lower surface thereof,
the first and second excitation electrodes being disposed on corners of the lower surface of the piezoelectric device, respectively.

4. The piezoelectric device package of claim 3, wherein the temperature measuring device has first piezoelectric device connecting electrodes disposed on some of corners thereof so as to correspond to the corners of the piezoelectric device on which the first and second excitation electrodes are disposed.

5. The piezoelectric device package of claim 1, wherein the piezoelectric device has dummy electrodes disposed on some corners of a lower surface thereof.

6. The piezoelectric device package of claim 1, wherein the plurality of terminals include a temperature measuring device input terminal, a temperature measuring device output terminal, a piezoelectric device input terminal, and a piezoelectric device output terminal respectively disposed corners of a lower surface of the case in a clockwise direction or a counterclockwise direction.

7. The piezoelectric device package of claim 1, wherein the cover member is disposed of a metal.

8. The piezoelectric device package of claim 7, wherein one of the terminals and the cover member are electrically connected to each other.

9. A method of fabricating a piezoelectric device package, comprising:
mounting a temperature measuring device having a thin film form in a case;
mounting a piezoelectric device in the case; and
coupling a cover member to an upper portion of the case.
